(19) United States
(12) Patent Application Publication
(10) Pub. No.: US 2023/0184105 A1
(43) Pub. Date: Jun. 15, 2023

(54) SELECTIVELY PREDICTING BREAKDOWN PRESSURES AND FRACTURING SUBTERRANEAN FORMATIONS

(71) Applicant: Saudi Arabian Oil Company, Dhahran (SA)

(72) Inventors: Yanhui Han, Houston, TX (US); Chao Liu, Brookshire, TX (US); Younane N. Abousleiman, Norman, OK (US)

(21) Appl. No.: 17/547,627

(22) Filed: Dec. 10, 2021

(51) Int. Cl. E21B 49/00; E21B 43/26; E21B 47/022; G01V 99/00

(52) U.S. Cl. CPC E21B 49/00; E21B 43/2607; E21B 47/022; G01V 99/00

(57) ABSTRACT

Some systems and methods of hydraulic fracturing a formation of a borehole include receiving a length-to-radius ratio of a borehole segment of the borehole and determining when the length-to-radius ratio is less than a threshold. Responsive to determining that the length-to-radius ratio is less than the threshold, some systems and methods include predicting a breakdown pressure associated with a formation surrounding the borehole segment based on a length of the borehole segment. Responsive to determining that the length-to-radius ratio is greater than or equal to the threshold, some systems and methods include determining, a characteristic diffusion time associated with a fluid diffusing into the formation surrounding the borehole segment. Some systems and methods include pumping the fluid into the borehole segment to fracture the formation surrounding the borehole segment at the determined breakdown pressure.

### TECHNICAL FIELD

This disclosure describes systems and methods for fracturing a subterranean formation, and more particularly, fracturing a subterranean formation based a predicted breakdown pressure.

### BACKGROUND

Hydraulic fracturing has been used to stimulate tight sandstone and shale gas reservoirs. Rock breakdown or fracture initiation is typically required for a successful hydraulic fracturing treatment. For hydraulic fracturing treatments, accurately estimating a breakdown pressure of a subsurface (or subterranean) formation may help determine correct selections of casing size, tubing size, and wellhead (for example, to correctly select their respective burst pressure limiting requirements), as well as a pump schedule design. Otherwise, the hydraulic fracturing operation may not properly inject a fracturing liquid to fracture the formation (for example, if the breakdown pressure was underestimated). Conventionally, hydraulic fracturing simulators may not accurately predict the breakdown pressure due to, for example, model simplifications.

### SUMMARY

The systems and methods described in this disclosure relate to fracturing of a subterranean formation surrounding a borehole segment of a borehole based on a prediction of breakdown pressure. A numerical model predicts the breakdown pressure by selecting one of four solution approaches based on a length-to-radius ratio of the borehole segment and a characteristic diffusion time associated with a fluid diffusing into the subterranean formation. The numerical model predicts the breakdown pressure of the borehole segment using the selected solution approach. The systems and methods determine a pumping schedule based on the predicted breakdown pressure and pump hydraulic fluid into the borehole segment to fracture the subterranean formation at the predicted breakdown pressure.

Accurately predicting the breakdown pressure of a formation surrounding a borehole can be challenging. In some examples, this is challenging because of unknown properties associated with the borehole. In some cases, the unknown properties include properties associated with the subterranean formation (for example, rock composition, in-situ stresses, and pore pressures) and determining these properties can be difficult. For example, the process of breaking down a subterranean formation inside a borehole by a fluid injection is affected by (1) the state and properties of the subterranean formation including in-situ stresses and pore pressure, the physical (for example, mechanical, hydraulic, thermal, chemical, and rheological) properties of the rock (for example, rock stiffness and strength, permeability, and thermal expansion coefficient); (2) well geometric parameters (for example, azimuth, inclination angle, borehole diameter, and interval length); and (3) injection system parameters (for example, pressurization rate, viscosity of injection fluid, and hydraulic compliance of the system).

Another reason why it can be difficult to accurately predict breakdown pressure in a borehole is because there is little margin for error. For example, if the breakdown pressure is predicted to be less than the actual breakdown pressure, then the subterranean formation may not fracture at all when a pump schedule is designed based on the under-predicted breakdown pressure. On the other hand, if the breakdown pressure is predicted to be greater than the actual breakdown pressure, then the pump schedule may fracture overburden and underburden layers surrounding the borehole when a pump schedule is designed based on the over-predicted breakdown pressure. If the over-prediction of breakdown pressure is severe enough, such fractures can lead to a compromise of the entire borehole.

Another reason why it can be difficult to accurately predict the breakdown pressure of a borehole is because many different solution approaches can be used to predict the breakdown pressure. Knowing when to select one approach over a different approach is difficult. The systems and methods described in this disclosure select a solution approach based on a combination of a spatial parameter (for example, the length-to-radius ratio of the borehole) and a temporal parameter (for example, the characteristic diffusion time of the fluid surrounding the borehole). In particular, using the length-to-radius ratio is important because this geometric parameter directly affects the spatial distribution and concentration of effective stresses near the wellbore. Using the characteristic diffusion time is important because this temporal parameter influences the time-dependent pore pressure distribution and evolution which indirectly introduces changes to the temporal variations to the effective stresses.

The control system 146 selects one of four solution approaches to predict the breakdown pressure of the subterranean formation 118. These solution approaches include (1) the solution approach developed by Hubbert and Willis in 1957 (“the HW solution approach”), (2) the solution approach developed by Haimson and Fairhurst in 1967 (“the HF solution approach”), (3) the solution approach developed by Tran, Abousleiman and Nguyen in 2011 (“the TAN solution approach”), and (4) the solution approach developed Abousleiman and Chen in 2010 (“the AC solution approach”).

The HW solution approach uses Kirsch solutions of stresses around a circular hole in an elastic medium and uses an equation for predicting breakdown pressure inside an impermeable borehole. The breakdown pressure is predicted based on in-situ principal stresses, reservoir pore pressure, and formation tensile strength.

The HF solution approach is based on a similarity between fluid and thermal diffusion around a circular borehole. The HF solution approach uses an equation for predicting breakdown pressure inside a permeable borehole, where the breakdown pressure is based on a Poisson's ratio and poroelastic parameter of the subterranean formation. The HF solution approach is also based on the same factors as the HW solution approach (for example, in-situ principal stresses, reservoir pore pressure, and formation tensile strength).

The TAN solution approach is based on a fluid-mechanical interaction during a fluid diffusion process around the borehole. The TAN solution approach uses poroelastic solutions of stresses and pore pressure around a vertical borehole in a non-hydrostatic stress field (for example, tangential stress exists around a borehole) and hydraulic properties of the rock surrounding the borehole. In some cases, the TAN solution approach also uses poroelastic stress solutions for an inclined borehole. An inclined borehole is defined by a length-radius ratio, a characteristic time of diffusion process (“the characteristic diffusion time”), and an injection time. In some cases, the TAN solution approach determines the injection time and pressure for the inclined borehole. In some cases, the TAN solution is based on a presence of filter cake within the borehole (for example, as formed during the drilling of the borehole).

The AC solution approach is based on a finite length of the borehole. In particular, the AC solution approach uses poroelastic solutions for injecting an inclined borehole of finite length. The AC solution approach indicates that a fluid discharge length can have a significant influence on the distribution and evolution of tangential stress around the borehole. The AC solution approach uses the finite length of the borehole and a length-to-radius ratio of the borehole to predict the breakdown pressure.

The systems and methods described in this disclosure implement computer software to integrate these four solution approaches (e.g., the HW, HF, TAN, and AC solution approaches) into a single implementation to select one of these solution approaches based on the length-to-radius ratio and the characteristic diffusion time associated with the borehole and the subterranean formation.

Some systems and methods for hydraulic fracturing a subterranean formation surrounding a borehole segment of a borehole include a well log instrument operable to measure a length-to-radius ratio of a borehole segment of a borehole. The systems and methods include a hydraulic pump operable to pump a fluid into the borehole. The systems and methods include one or more processors configured to perform one or more operations. The operations include receiving the measured length-to-radius ratio of the borehole segment from the well log instrument. The operations include determining a characteristic diffusion time associated with the fluid when pumped into a formation surrounding the borehole segment. The operations include selecting a breakdown pressure solution approach based on (i) the measured length-to-radius ratio of the borehole segment and (ii) the characteristic diffusion time associated with a diffusion of the fluid into the formation surrounding the borehole segment. The operations include predicting the breakdown pressure of the formation surrounding the borehole segment using the selected breakdown pressure solution approach. The operations include controlling the hydraulic pump to pump the fluid into the borehole segment at a pressure greater than or equal to the predicted breakdown pressure to fracture the formation surrounding the borehole segment.

In some implementations, the operation of selecting the breakdown pressure solution approach includes determining when the characteristic diffusion time is at least 10 times greater than an injection time. In some cases, the injection time represents a duration of time associated with the fluid being pumped into the borehole segment by the pump. In some cases, the operation of predicting the breakdown pressure includes the operations described in the following paragraph.

Responsive to determining that the characteristic diffusion time is at least 10 times greater than the injection time, the operations include predicting the breakdown pressure based on in-situ principal stresses acting on the borehole segment, a reservoir pore pressure of the formation, and a tensile strength of the formation. Responsive to determining that the characteristic diffusion time is at least 10 times less than the injection time, the operations include predicting the breakdown pressure based on a Poisson's ratio of the formation and a poroelastic parameter of the formation. Responsive to determining that the characteristic diffusion time is neither at least 10 times less nor at least 10 times greater than the injection time, the operations include predicting the breakdown pressure based on a hydraulic property of the formation.

Some systems and methods for hydraulic fracturing a subterranean formation surrounding a borehole segment of a borehole perform operations of receiving, by a processor, a length-to-radius ratio of a borehole segment of the borehole. The operations include determining, by the processor, a characteristic diffusion time associated with a fluid when pumped into the formation surrounding the borehole segment. The operations include selecting, by the processor, a breakdown pressure solution approach based on the length-to-radius ratio of the borehole segment and the characteristic diffusion time associated with the fluid. The operations include predicting, by the processor, a breakdown pressure of the formation surrounding the borehole segment using the selected breakdown pressure solution approach. The operations include pumping, by a hydraulic pump, the fluid into the borehole segment to fracture the formation at the predicted breakdown pressure.

In some implementations, the operations include measuring, by a well log instrument, the length-to-radius ratio of the borehole segment.

In some implementations, the operation of determining the characteristic diffusion time associated with the fluid when pumped into the formation surrounding the borehole segment includes evaluating an expression as a function of a diffusivity of the fluid and a diffusion length of the formation.

Some systems and methods for hydraulic fracturing a subterranean formation surrounding a borehole segment of a borehole perform operations including receiving, by a processor, a length-to-radius ratio of a borehole segment of the borehole. The operations include determining, by the processor, when the length-to-radius ratio is less than a threshold. Responsive to determining that the length-to-radius ratio is less than the threshold, the operations include predicting, by the processor, a breakdown pressure associated with a formation surrounding the borehole segment based on a length of the borehole segment. Responsive to determining that the length-to-radius ratio is greater than or equal to the threshold, the systems and methods perform the operations described in the following paragraph.

In some implementations, the operations include determining, by the processor, a characteristic diffusion time associated with a fluid diffusing into the formation surrounding the borehole segment. The operations include determining, by the processor, whether the characteristic diffusion time is at least 10 times greater than an injection time associated with the fluid in the formation surrounding the borehole segment. The injection time represents a duration of time associated with the fluid being pumped into the borehole segment. Responsive to determining that the characteristic diffusion time is at least 10 times greater than the injection time, the operations include predicting, by the processor, the breakdown pressure based on in-situ principal stresses acting on the borehole segment, reservoir pore pressure of the formation, and a tensile strength of the formation. Responsive to determining that the characteristic diffusion time is at least 10 times less than the injection time, the operations include predicting, by the processor, the breakdown pressure based on a Poisson's ratio of the formation and a poroelastic parameter of the formation. Responsive to determining that the characteristic diffusion time is neither at least 10 times less nor at least 10 times greater than the injection time, the operations include predicting the breakdown pressure based on a hydraulic property of the formation.

In some implementations, the operations include pumping, by a hydraulic pump, the fluid into the borehole segment of the borehole to cause the formation surrounding the borehole segment to fracture at the predicted breakdown pressure.

In some implementations, the operations further include measuring the length-to-radius ratio of the borehole segment of the borehole. In some cases, the operation of measuring the length-to-radius ratio of the borehole segment of the borehole includes logging the borehole to produce one or more well logs, and using the one or more well logs to determine the length-to-radius ratio.

In some examples, the borehole segment is a perforation channel of the borehole. In some cases, threshold is between 5 and 15. In some cases, the threshold is 10.

In some implementations, the operation of predicting the breakdown pressure based on the hydraulic property of the formation includes predicting the breakdown pressure based on the hydraulic property of the formation and a presence of filter cake or mud cake within the formation.

In some implementations, the operations further include receiving, by the processor, an inclination angle of the borehole segment. In some cases, the operations include transforming, by the processor, the in-situ principal stresses associated with formation surrounding the borehole segment based of the inclination angle of the borehole segment. In some cases, the operations further include logging the borehole to produce one or more well logs and using the one or more well logs to determine the inclination angle of the borehole segments.

In some implementations, the operation of predicting the breakdown pressure based on the in-situ principal stresses acting on the borehole segment, the reservoir pore pressure of the formation, and the tensile strength of the formation, includes evaluating: P_{b}=3σ₃−σ₁+T+P₀, where P_{b} is the breakdown pressure, σ₃ is a minimum in-situ principal stress along a first transverse direction of the borehole segment, σ₁ is a maximum in-situ principal stress along a second transverse direction of the borehole segment, T is the tensile strength of the formation, and P₀ is the reservoir pore pressure of the borehole. In some examples, the second transverse direction is perpendicular to the first transverse direction.

In some implementations, the operation of determining the breakdown pressure based on the Poisson's ratio of the formation and the poroelastic parameter of the formation includes evaluating:

$${P}_{b} = \frac{3 {σ}_{3} - {σ}_{1} - 2 {P}_{0} + T}{2 - α \frac{1 - 2 v}{1 - v}} + {P}_{0} ,$$

where P_{b} is the breakdown pressure, σ₃ is a minimum in-situ principal stress along a first transverse direction of the borehole segment, σ₁ is a maximum in-situ principal stress along a second transverse direction of the borehole segment, T is the tensile strength of the formation, P₀ is the reservoir pore pressure of the formation, α is a Biot coefficient of effective stress of the formation, and v is a Poisson's ratio of the formation. In some examples, the second transverse direction is perpendicular to the first transverse direction.

In some implementations, the operation of determining the breakdown pressure based on the length of the borehole segment and predicting the breakdown pressure based on a hydraulic property of the formation includes determining one or more Laplace and Fourier transforms.

In some implementations, the operation of determining the characteristic diffusion time associated with the fluid in the formation surrounding the borehole segment includes evaluating:

$${t}_{c} = \frac{{L}_{c}^{2}}{c} ,$$

where L_{c} is the characteristic diffusion time, c is a diffusivity of the fluid in the formation, and L_{c} is a diffusion length. In some cases, the operations include determining the diffusion length of the formation using a simulation model of the borehole.

The systems and methods described in this disclosure improve accuracy of the breakdown pressure prediction by accounting for multiple different solution approaches and selecting the appropriate solution approach based on spatial and temporal characteristics of the specific engineering scenario.

For ease of description, terms such as “upper”, “lower”, “top”, “bottom” “left” and “right” are relative to the orientation of the features in the figures rather than implying an absolute direction.

The details of one or more embodiments of these systems and methods are set forth in the accompanying drawings and the description below. Other features, objects, and advantages of these systems and methods will be apparent from the description and drawings, and from the claims.

### DESCRIPTION OF DRAWINGS

FIG. 1 is a schematic side view of an example wellbore system.

FIGS. 2A-2B is a method for predicting breakdown pressure and fracturing a borehole.

FIGS. 3A-3B are schematics of a stress transformation for an inclined borehole segment. FIG. 3A is a schematic of in-situ stresses acting on the inclined borehole in a global Earth coordinate system. FIG. 3B is a schematic of equivalent far-field stresses acting on the inclined borehole in a local cylindrical coordinate system of the borehole.

FIG. 4 is a schematic of a plane strain borehole model of a borehole.

FIG. 5 is a schematic of a finite-length borehole segment.

FIG. 6 is a decision process for predicting breakdown pressure of a borehole.

FIG. 7 is a method for predicting breakdown pressure and fracturing a borehole.

FIG. 8 is a block diagram of a computer system.

Like reference symbols in the various drawings indicate like elements.

### DETAILED DESCRIPTION

The systems and methods described in this disclosure relate to fracturing of a subterranean formation surrounding a borehole segment of a borehole based on a prediction of breakdown pressure. A numerical model predicts the breakdown pressure by selecting one of four solution approaches based on a length-to-radius ratio of the borehole segment and a characteristic diffusion time associated with a fluid diffusing into the subterranean formation. The numerical model predicts the breakdown pressure of the borehole segment using the selected solution approach. The systems and methods determine a pumping schedule based on the predicted breakdown pressure and pump hydraulic fluid into the borehole segment to fracture the subterranean formation at the predicted breakdown pressure.

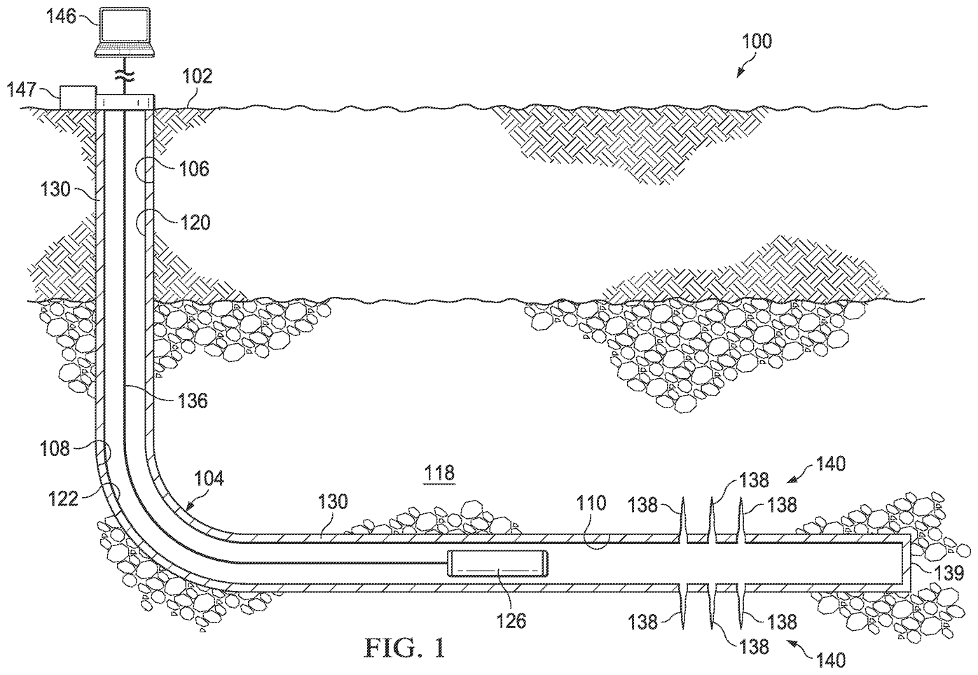

FIG. 1 is a schematic diagram of an example implementation of a wellbore system 100 according to the present disclosure. In some aspects, the wellbore system 100 (all or part of it) includes a computational framework (for example, control system 146) for predicting the breakdown pressure of a subterranean formation 118. The wellbore system 100 includes one or more boreholes and/or one or more borehole segments. For example, the wellbore system 100 includes a borehole 104 formed (for example, drilled or otherwise) from a ground surface 102 into the subterranean formation 118. Although the ground surface 102 is illustrated as a land surface, the ground surface 102 may be a sub-sea or other underwater surface, such as a lake or an ocean floor or other surface under a body of water. The borehole 104 may be formed under a body of water from a drilling location on or proximate the body of water.

The borehole 104 is a directional borehole that includes a substantially vertical portion 106 coupled to a radiused or curved portion 108, which in turn is coupled to a substantially horizontal portion 110. The three portions of the borehole 104—the vertical portion 106, the radiused portion 108, and the horizontal portion 110—form a continuous borehole 104 that extends into the Earth.

As used in the present disclosure, “substantially” in the context of a borehole orientation, refers to boreholes that may not be exactly vertical (for example, exactly perpendicular to the ground surface 102) or exactly horizontal (for example, exactly parallel to the ground surface 102). In some cases, the borehole 104 is inclined relative to the ground surface 102. In other words, those of ordinary skill in the drill arts would recognize that vertical boreholes often undulate offset from a true vertical direction that they might be drilled at an angle that deviates from true vertical, and horizontal boreholes often undulate offset from a true horizontal direction. Further, the substantially horizontal portion 110, in some aspects, may be a slant borehole or other directional borehole that is oriented between exactly vertical and exactly horizontal. The substantially horizontal portion 110, in some aspects, may be oriented to follow a slant of the formation. At least a portion of the borehole 104, such as the radiused portion 108 and the horizontal portion 110, may be considered an inclined or deviated borehole, in other words, a non-vertical borehole.

The borehole 104 has a surface casing 120 positioned and set around the borehole 104 from the ground surface 102 into a particular depth in the Earth. For example, the surface casing 120 may be a relatively large-diameter tubular member (or string of members) set (for example, cemented) around the borehole 104 in a shallow formation. As used herein, “tubular” may refer to a member that has a circular cross-section, elliptical cross-section, or other shaped cross-section. As illustrated, a production casing 122 is positioned and set within the borehole 104 downhole of the surface casing 120. Although termed a “production” casing, in this example, the casing 122 may or may not have been subject to hydrocarbon production operations. Thus, the casing 122 refers to and includes any form of tubular member that is set (for example, cemented) in the borehole 104 downhole of the surface casing 120. In some examples of the wellbore system 100, the production casing 122 may begin at an end of the radiused portion 108 and extend throughout the substantially horizontal portion 110. The casing 122 could also extend into the radiused portion 108 and into the vertical portion 106.

Cement 130 is positioned (for example, pumped) around the casings 120 and 122 in an annulus between the casings 120 and 122 and the borehole 104. The cement 130, for example, may secure the casings 120 and 122 (and any other casings or liners of the borehole 104) through the subterranean layers under the ground surface 102. In some aspects, the cement 130 may be installed along the entire length of the casings (for example, casings 120 and 122 and any other casings), or the cement 130 could be used along certain portions of the casings if adequate for the particular borehole 104. Other casings, such as conductor casings or intermediate casings, can be used in the wellbore system 100.

The borehole 104 extends through one or more subterranean layers (not specifically labeled) and lands in subterranean formation 118. The subterranean formation 118, in this example, may be chosen as the landing for the substantially horizontal portion 110, for example, in order to initiate completion operations such as hydraulic fracturing operations and ultimately recover hydrocarbon fluids from the subterranean formation 118. In some examples, the subterranean formation 118 is composed of shale or tight sandstone. Shale, in some examples, may be source rocks that provide for hydrocarbon recovery from the subterranean formation 118.

The borehole 104 includes one or more perforation channels 138 that radially extend from the borehole 104. In some examples, the perforation channels 138 extend through the casing 122 and the cement 130, and into the subterranean formation 118. In some examples, the one or more perforation channels 138 are the borehole segments. Generally, a borehole segment is length segment of the borehole where fracturing operations are desired. In some examples, the borehole segment is some of the perforation channels 138. In some examples, the borehole segment is an end segment 139 of the borehole 104.

In some examples, the perforation channels 138 are formed by, for example, shaped explosive charges, water jetting, laser, or other conventional perforating techniques. In some aspects, multiple perforation channels 138 may include a perforation stage 140. Each perforation channels 138, as well as each perforation cluster 140, may provide a path (or paths) for a hydraulic fracturing liquid (with or without proppant) to enter the subterranean formation 118 from the borehole 104 in order to initiate and propagate hydraulic fractures (extending from the perforation channels 138) through the subterranean formation 118. In some examples, the perforation channels 138 and/or the borehole 104 contains mud.

The wellbore system 100 includes a well log instrument 126 communicably coupled to a downhole conveyance 136, such as a wirelines, optical line, or other data communication cable. The downhole conveyance 136 provides data from the well log instrument 126 to the control system 146, for real time (for example, during logging operations) or later usage in measuring one or more properties of the borehole 104.

In some examples, the data from the well log instrument 126 represents geometric data associated with a borehole segment of the borehole 104 and includes information regarding a length of the borehole segment, a radius of the borehole segment, an inclination angle of the borehole segment, and/or an azimuth angle of the borehole segment. In some examples, the data from the well log instrument 126 represents information identifying a rock of the subterranean formation 118. In some examples, the data represents information about a permeability of the rock. In some examples, the data from the well log instrument 126 represents information about a thickness of filter cake within and/or surrounding the borehole segment. In some examples, the data represents information about a permeability of the filter cake. In some examples, the data from the well log instrument 126 represents information about in-situ stresses and/or pore pressures within and/or surrounding the borehole segment.

In some examples, the control system 146 includes a microprocessor based control system that includes, for example, one or more hardware processors, one or more memory storage devices (for example, tangible, non-transitory computer-readable memory modules), one or more network interfaces, and one or more input/output devices, including, for example, a graphical user interface (GUI) to present one or more determinations or data from the computer framework for predicting the breakdown pressure of the subterranean formation 118.

In some examples, the control system 146 implements computer software to determine the breakdown pressure associated with one or more borehole segments of the borehole 104. For example, the one or more of the perforation channels 138 of the borehole 104 or the end segment 139 of the borehole 104. In some examples, the control system 146 is located on-site at the borehole 104. For example, the control system 146 can be located within an on-site building, trailer, or vehicle. In some examples, the control system 146 is located off-site from the borehole 104. For example, the control system 146 can be located at a remote data center or an engineering facility.

The wellbore system 100 includes a hydraulic pump 147 operable to pump a fluid into the borehole 104 to fracture the borehole segment. The hydraulic pump 147 pumps fluid into the borehole 104 with a pressure approximately equal to the predicted breakdown pressure to fracture the subterranean formation 118 surrounding the borehole segment. The control system 146 controls the hydraulic pump 147 to pump the hydraulic fluid into the borehole 104 and into the borehole segment.

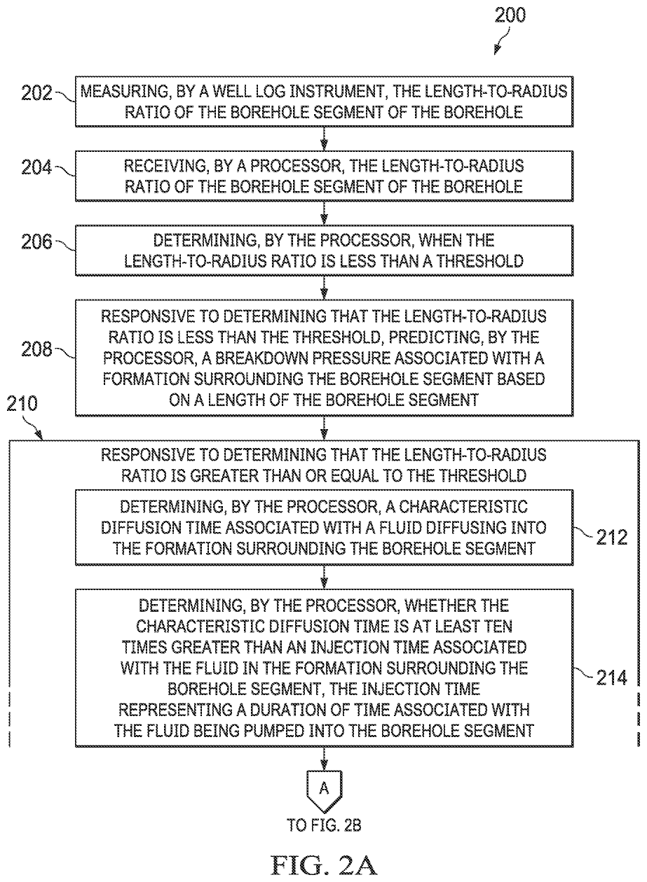

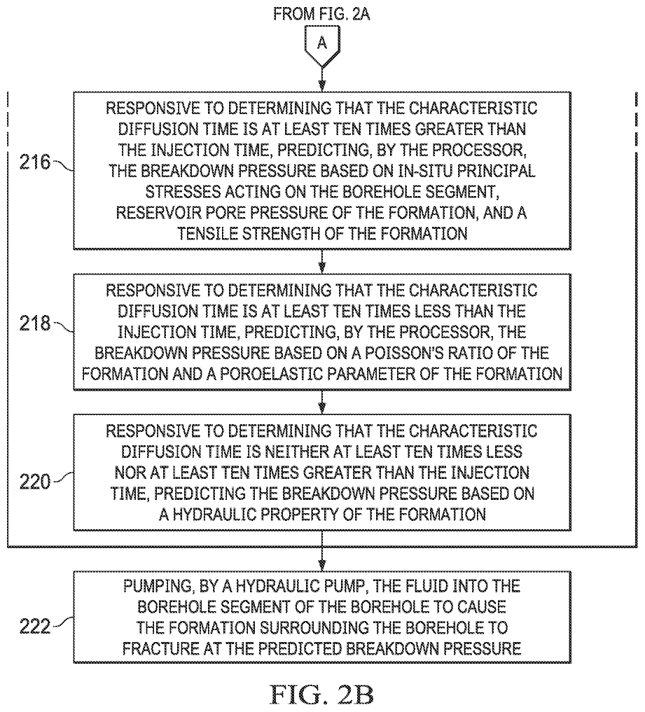

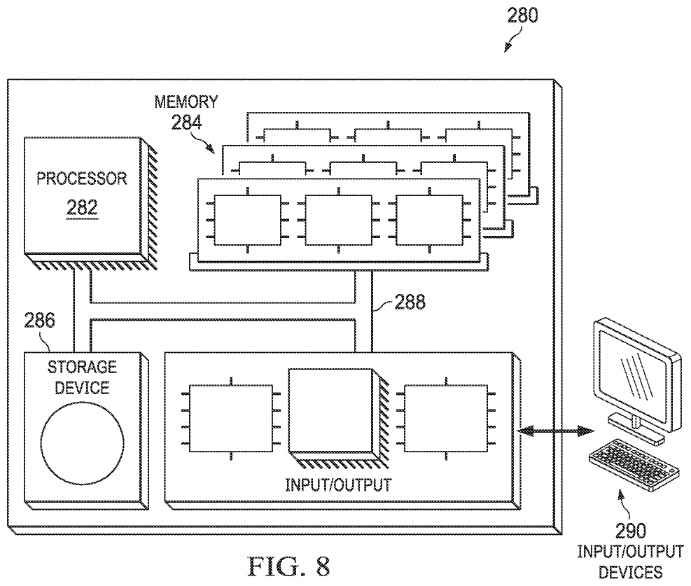

FIGS. 2A-2B are a flowchart of a method 200 for predicting the breakdown pressure of a subterranean formation (for example, the subterranean formation 118). In some examples, the control system 146 of the wellbore system 100 performs one or more steps of the method 200. In some examples, the well log instrument 126 and/or the hydraulic pump 147 of the wellbore system 100 perform one or more steps of the method 200. In some examples, one or more computer systems 280 described with reference to FIG. 8 perform one or more steps of the method 200.

At step 202, a well log instrument measures a length-to-radius ratio of a borehole segment of a borehole. For example, the well log instrument 126 measures a length and a radius (or a diameter) of a borehole segment of the borehole 104 (for example, one of the perforation channels 138 or the end segment 139) and the wellbore system 100 determines a length-to-radius ratio based on the measured length and radius (or diameter). In some examples, measuring the length-to-radius ratio of the borehole segment includes logging the borehole 104 to produce one or more well logs, and using the one or more well logs to determine the length-to-radius ratio.

In some examples, the well log instrument 126 measures information about the inclination angle and information about the azimuth angle of the borehole segment. In some examples, the determination of the inclination angle of the borehole segment is based on one or more well logs generated by the well log instrument 126. In some examples, the well log instrument 126 measures information about the in-situ stresses and pore pressures within the borehole segment. In some examples, the well log instrument 126 measures information about the rock of the subterranean formation 118. For example, the well log instrument 126 measures a tensile strength and a rock permeability of the rock. In some examples, the well log instrument 126 measures information about filter cake thickness and permeability within and/or surrounding the borehole segment. In some examples, information about the in-situ stresses is determined based on a density log of the borehole 104.

In some examples, the wellbore system 100 transforms the in-situ stresses from a global Earth coordinate system to a local coordinate system of the borehole segment. For example, the wellbore system 100 transforms the in-situ stresses measured by the well log instrument 126 to a local coordinate system of the borehole segment based on the measured geometric data including the length, the radius, the inclination angle, and/or the azimuth of the borehole segment. In some examples, the wellbore system 100 transforms the in-situ stresses using Eq. (1) (described below).

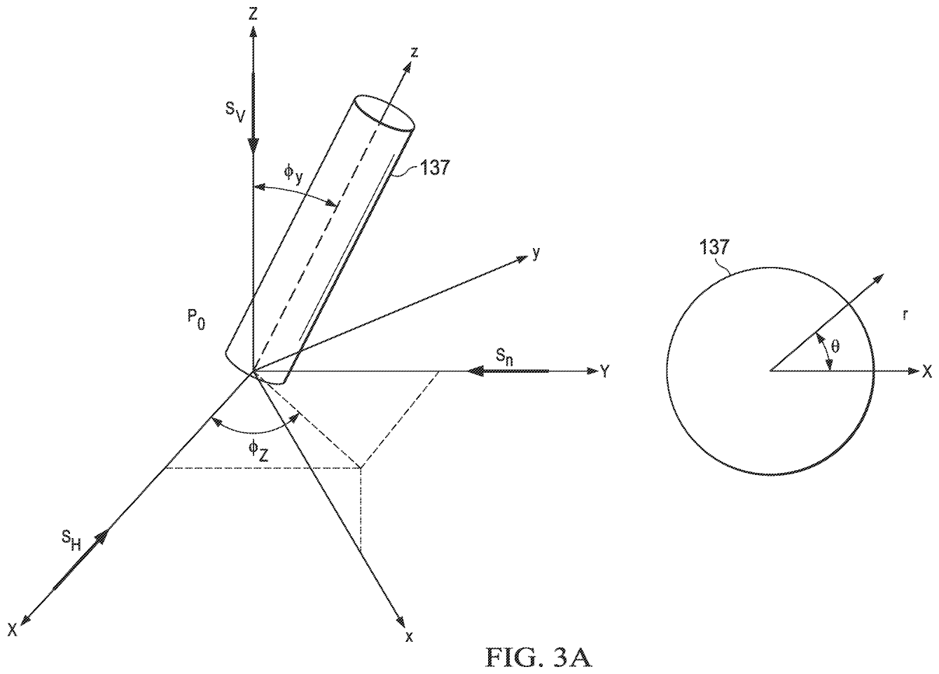

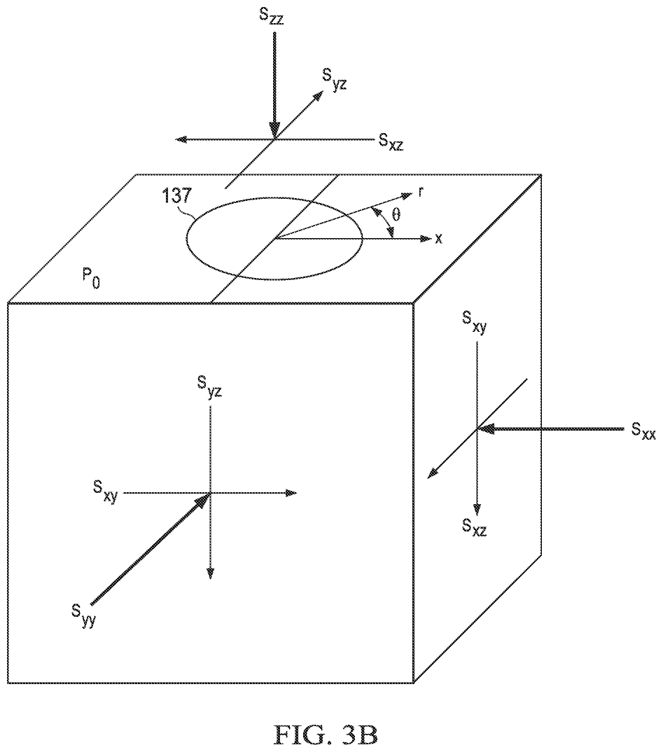

FIGS. 3A and 3B illustrate the stresses and pressures acting on a borehole segment. FIG. 3A illustrates a borehole segment 137 subjected to vertical in-situ stress (Sv) and horizontal in-situ stresses (Sₙ and S_{H}) with respect to a global Earth coordinate system and pore pressure (P₀) independent of a particular coordinate system. In some examples, the in-situ stresses result from a presence of overburden and/or underburden proximal to the subterranean formation 118.

The wellbore system 100 transforms the in-situ stresses from the global Earth coordinate system to a local cylindrical borehole coordinate system of the borehole segment 137 based on inclination angles ( _{y} and φ_{z}) of the inclined borehole segment 137. In some examples, the wellbore system 100 transforms the in-situ stresses based on the transformation of Eq. (1).

$$[ \begin{matrix}{S}_{xx} \\ {S}_{yy} \\ {S}_{zz} \\ {S}_{xy} \\ {S}_{xz} \\ {S}_{yz}\end{matrix} ] = [ \begin{matrix}{cos}^{2} {φ}_{z} {cos}^{2} {φ}_{y} & {sin}^{2} {φ}_{z} {cos}^{2} {φ}_{y} & {sin}^{2} {φ}_{y} \\ {sin}^{2} {φ}_{z} & {cos}^{2} {φ}_{z} & 0 \\ {cos}^{2} {φ}_{z} {sin}^{2} {φ}_{y} & {sin}^{2} {φ}_{z} {sin}^{2} {φ}_{y} & {cos}^{2} {φ}_{y} \\ - cos {φ}_{z} cos {φ}_{y} sin {φ}_{z} & sin {φ}_{z} cos {φ}_{y} cos {φ}_{z} & 0 \\ {cos}^{2} {φ}_{z} cos {φ}_{y} sin {φ}_{y} & {sin}^{2} {φ}_{z} cos {φ}_{y} sin {φ}_{y} & sin {φ}_{y} cos {φ}_{y} \\ - cos {φ}_{z} sin {φ}_{y} sin {φ}_{z} & sin {φ}_{z} sin {φ}_{y} cos {φ}_{z} & 0\end{matrix} ] [ \begin{matrix}{S}_{H} \\ {S}_{h} \\ {S}_{V}\end{matrix} ] \qquad Eq . ( 1 )$$

FIG. 3B illustrates an angular position (θ) around the borehole segment 137 and illustrates a radius (r) representing a length into the subterranean formation 118. FIG. 2C is a schematic illustrating a general stress state involving the transformed in-situ stresses of Eq. (1). In particular, the six transformed stresses include three normal in-situ stresses (Sₓₓ, S_{yy}, and S_{zz}) and three shear in-situ stresses (S_{xy}, S_{zy}, S_{yz}). Conservation of momentum dictates that S_{xy}=S_{yx}, S_{zy}=S_{yz}, and S_{yz}=S_{zy}.

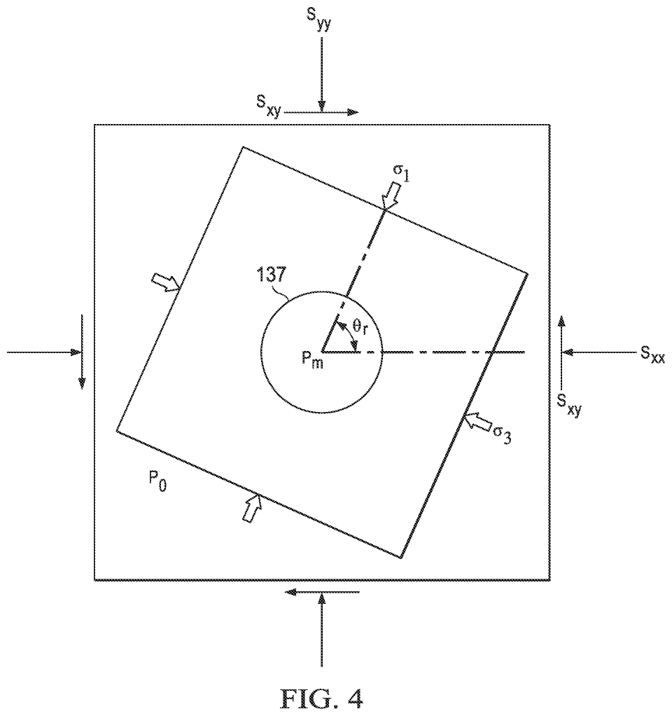

FIG. 4 is a schematic of a two-dimensional plane-strain approximation of stress state of the borehole segment 137. In the example shown in FIG. 4, far-field in-situ stresses Sₓₓ, S_{yy} and S_{xy} apply stress on the perforation channel 138 and mud pressure μm applies pressure inside the perforation channel 138. In some examples, “far-field” represents a length of at least three diameters away from the perforation channel 138. The wellbore system 100 determines the principal stresses σ₁ and σ₃ by transforming the stresses, Sₓₓ, S_{yy} and S_{xy}. As shown in FIG. 4, the principal stresses act on the borehole segment 137 in the far-field in a similar manner as the Sₓₓ, S_{yy} and S_{xy} stresses.

In some examples, the wellbore system 100 determines σ₁, σ₃ and θᵣ based on the transformations of Eqs. (2)-(4).

$${σ}_{1} = \frac{{S}_{x x} + {S}_{y y}}{2} + \frac{\sqrt{{( {S}_{x x} - {S}_{y y} )}^{2} + 4 {S}_{xy}^{2}}}{2} \qquad Eq . ( 2 )$$

$${σ}_{3} = \frac{{S}_{x x} + {S}_{y y}}{2} - \frac{\sqrt{{( {S}_{x x} - {S}_{y y} )}^{2} + 4 {S}_{xy}^{2}}}{2} \qquad Eq . ( 3 )$$

$${θ}_{r} = \frac{1}{2} {tan}^{- 1} \frac{2 {S}_{xy}}{{S}_{x x} - {S}_{y y}} \qquad Eq . ( 4 )$$

In some examples, the wellbore system 100 receives an inclination angle of the borehole segment 137 and transforms the in-situ principal stresses associated with subterranean formation 118 surrounding the borehole segment 137 based of the inclination angle of the borehole segment 137. The wellbore system 100 uses the principal stresses determined from Eqs. (2) and (3) to predict the breakdown pressure of the borehole segment 137. This process is further described with reference to the specific solution approaches of method 200.

At step 204, the wellbore system 100 receives the length-to-radius ratio of the borehole segment of the borehole. For example, a processor of the control system 146 receives the length-to-radius ratio of the borehole segment 137 of the borehole 104. As noted previously, in some examples, the borehole segment 137 is one of the perforation channels 138. In some examples, the borehole segment 137 is the end segment 139 of the borehole 104.

At step 206, the wellbore system 100 determines when the length-to-radius ratio is less than a threshold. In some examples, the threshold is between 5 and 15. In some examples, the threshold is 10. This threshold is used to identify when infinite length approximations are valid. For example, if the length-to-radius ratio is less than 10, then the wellbore system 100 determines that a finite-length solution approach is applicable. On the other hand, if the length-to-radius ratio is greater than 10, then the wellbore system 100 determines that an infinite-length solution approach is applicable. Accounting for the finite length of the borehole segment 137 in the breakdown pressure prediction can be important when the length-to-radius ratio of the borehole segment 137 is less than the threshold.

At step 208, responsive to determining that the length-to-radius ratio is less than the threshold, the wellbore system 100 predicts a breakdown pressure associated with a formation surrounding the borehole segment based on a length of the borehole segment. In some examples, the wellbore system 100 predicts the breakdown pressure based on the AC solution approach as part of step 208. As noted previously, the AC solution approach is adapted from the work of Abousleiman and Chen in 2010.

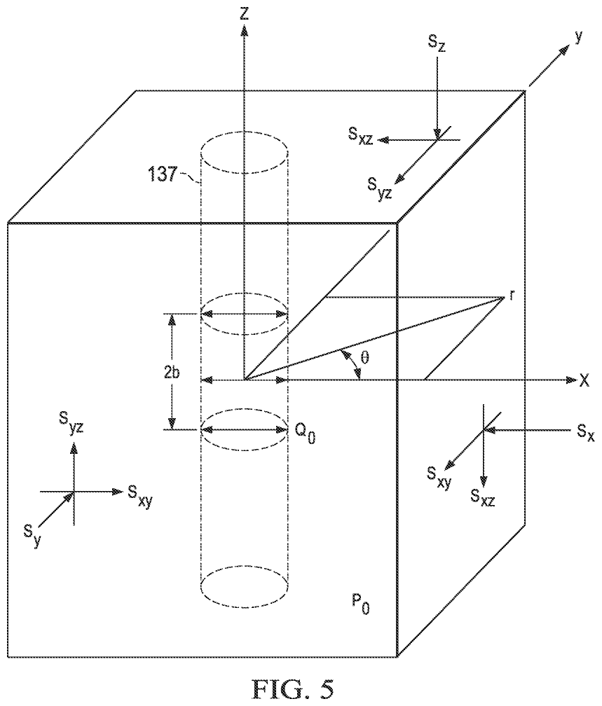

FIG. 5 is a schematic of the stresses acting on a finite-length borehole segment 137. In FIG. 5, h is the length of borehole segment 137. In some examples, the length is 2b instead of b to account for symmetry. The wellbore system 100 determines the time-dependent variations of stresses and pore pressure around the borehole segment 137.

In some examples, determining the breakdown pressure based on the length of the borehole segment 137 includes determining one or more Laplace and Fourier transforms. In some examples, the wellbore system 100 determines the evolution of the tangential stress (σ_{θθ}) and pore pressure (P) in time domain by applying Laplace and Fourier inversion. For example, the wellbore system 100 determines a poroelastic solution of tangential stress around the borehole segment 137 by evaluating the Laplace transformation of Eq. (5) and the wellbore system 100 determines a poroelastic solution of pore pressure around the borehole segment 137 by evaluating the Laplace transformation of Eq. (6).

$${\tilde{σ}}_{θ θ} = 2 G \{ \frac{B ( 1 + {v}_{u} )}{3 ( 1 - {v}_{u} )} {C}_{1} \frac{{K}_{1} ( \sqrt{\frac{s}{c} r} )}{\sqrt{\frac{s}{c} r}} + \frac{{C}_{2}}{{r}^{2}} \} - \frac{2 GBv ( 1 + {v}_{u} )}{3 ( 1 - 2 v ) ( 1 - {v}_{u} )} {C}_{1} {K}_{0} ( \sqrt{\frac{s}{c} r} ) + \frac{α c}{κ} {C}_{1} {K}_{0} ( \sqrt{\frac{s}{c} r} ) + \{ \frac{2 GB ( 1 + {v}_{u} )}{3 ( 1 - {v}_{u} )} {C}_{3} [ \frac{{K}_{1} ( \sqrt{\frac{s}{c} r} )}{\sqrt{\frac{s}{c} r}} + ( 1 + \frac{6}{{r}^{2 \frac{s}{c}}} ) {K}_{2} ( \sqrt{\frac{s}{c} r} ) + \frac{6 {GC}_{5}}{{r}^{4}} ] \} cos [ 2 ( θ - {θ}_{r} ) ] \qquad Eq . ( 5 )$$

$$\tilde{P} = \frac{c}{κ} {C}_{1} {K}_{0} ( \sqrt{\frac{s}{c} r} ) + ⌈ \frac{2 {{GB}^{2} ( 1 + {v}_{u} )}^{2} ( 1 - v )}{9 ( {v}_{u} - v ) ( 1 - {v}_{u} )} {C}_{3} {K}_{2} ( \sqrt{\frac{s}{c} r} ) -- \frac{2 GB ( 1 + {v}_{u} ) {C}_{4}}{3 ( 1 - {v}_{u} ) {r}^{2}} ⌉ cos [ 2 ( θ - {θ}_{r} ) ] \qquad Eq . ( 6 )$$

The wellbore system 100 determines the parameters of Eqs. (5) and (6) by evaluating Eqs. (7)-(13).

$${C}_{1} = \frac{s \hat{g} ( s ) {\tilde{P}}_{m} - \tilde{g} ( s ) {P}_{0}}{μ R \sqrt{cs} {K}_{1} ( \sqrt{\frac{s}{c}} R ) + \frac{c}{κ} s \tilde{g} ( s ) {K}_{0} ( \sqrt{\frac{s}{c}} R )} \qquad Eq . ( 7 )$$

$${C}_{2} = \frac{{R}^{2}}{2 G} [ - {\tilde{P}}_{m} + \frac{{M}_{0}}{s} - \frac{2 GB ( 1 + {v}_{u} )}{3 ( 1 + {v}_{u} )} {C}_{1} \frac{{K}_{1} ( \sqrt{\frac{s}{c}} R )}{\sqrt{\frac{s}{c}} R} ] \qquad Eq . ( 8 )$$

$${C}_{3} = - \frac{{S}_{0}}{s} \frac{4 + 2 \frac{s \tilde{g} ( s )}{{k}_{f}}}{{D}_{1} - {D}_{2}} \qquad Eq . ( 9 )$$

$${C}_{4} = - \frac{{S}_{0}}{s} \frac{2 ( 1 - {v}_{u} ) {R}^{2}}{G} \frac{{D}_{2}}{{D}_{1} - {D}_{2}} \qquad Eq . ( 10 )$$

$${C}_{5} = \frac{{S}_{0}}{s} \frac{{R}^{4} ( \frac{4}{\sqrt{\frac{s}{c}} R} \frac{{K}_{2} ( \sqrt{\frac{s}{c}} R )}{{K}_{1} ( \sqrt{\frac{s}{c}} R )} {D}_{1} + {D}_{1} + {D}_{2} )}{2 G ( {D}_{1} - {D}_{2} )} \qquad Eq . ( 11 )$$

$${D}_{1} = \frac{2 GB ( 1 + {v}_{u} )}{3 ( 1 - {v}_{u} )} \frac{{K}_{1} ( \sqrt{\frac{s}{c}} R )}{\sqrt{\frac{s}{c}} R} ( 2 + \frac{s \hat{g} ( s )}{{k}_{f}} ) \qquad Eq . ( 12 )$$

$${D}_{2} = \frac{GB ( 1 + {v}_{u} ) ( 1 - v )}{3 ( {v}_{u} - v ) ( 1 - {v}_{u} )} [ \text{} {K}_{2} ( \sqrt{\frac{s}{c}} R ) \frac{s \hat{g} ( s )}{{k}_{f}} + R \sqrt{\frac{s}{c}} {K}_{1} ( \sqrt{\frac{s}{c}} R ) + 2 {K}_{2} ( \sqrt{\frac{s}{c}} R ) ] \qquad Eq . ( 13 )$$

The wellbore system 100 determines the evolution of the tangential stress (ago) and pore pressure (P) in the time domain by applying a Laplace inversion to Eqs. (5) and (6). The wellbore system 100 predicts the breakdown pressure (P_{b}) based on the borehole pressure Pₘ for which the peak value of the effective tangential stress on the borehole segment 137 wall first exceeds the tensile strength T. The wellbore system 100 predicts the breakdown pressure by evaluating Eq. (14).

(σ_{θθ}−P)_{r=R}=T Eq. (14)

In some examples, solving Eq. (14) involves solving for many nonlinear terms which can be difficult. In some examples, the wellbore system 100 predicts the breakdown pressure by iteratively changing the pressure and calculating the effective stress at one or more critical spots on the borehole segment 137 wall in the time domain of interest to predict the breakdown pressure, P_{b}.

Referring back to FIG. 2A, at step 210, responsive to determining that the length-to-radius ratio is greater than or equal to the threshold, the wellbore system 100 performs steps 212 and 214 and at least one of steps 216, 218, and 220 depending on a relation of the characteristic diffusion time determined in step 212 to the injection time determined in step 214.

At step 212, the wellbore system 100 determines a characteristic diffusion time associated with a fluid in the formation surrounding the perforation channel. For example, determining the characteristic diffusion time includes evaluating Eq. (15).

$${t}_{c} = \frac{{L}_{c}^{2}}{c} \qquad Eq . ( 15 )$$

In Eq. (15), t_{c} is the characteristic diffusion time, c is a diffusivity of the fluid in the subterranean formation 118, and L_{c} is a diffusion length. In some examples, the wellbore system 100 determines the diffusion length of the subterranean formation 118 using a simulation model of the borehole 104. In some examples, wellbore system 100 determines the diffusion length to be five times the radius of borehole segment 137. In some cases, stress concentrations at distances of 5R (and greater) are small (for example, less than 5%). In some examples, wellbore system 100 determines the diffusion length to be greater five times the radius of borehole segment 137. In some examples, evaluating Eq. (17) includes determining the diffusivity by evaluating Eq. (16).

$$c = \frac{k}{S} \qquad Eq . ( 16 )$$

In Eq. (16), c is the diffusivity of the fluid in the formation, k is a permeability of the subterranean formation 18, and S is a storativity of the subterranean formation 118. In some examples, evaluating Eq. (16) includes determining the storativity by evaluating Eq. (17).

$$S = \frac{1}{M} + \frac{{α}^{2}}{K + 4 G / 3} \qquad Eq . ( 17 )$$

In Eq. (17), S is the storativity, M is a Biot modulus of the formation, a is Biot's coefficient of effective stress, K is a drained bulk modulus of the subterranean formation 118 and G is a shear modulus of the subterranean formation 118. In some examples, evaluating Eq. (17) includes determinin the Biot modulus of the formation by evaluating Eq. (18).

$$M = \frac{{K}_{f}}{n + ( α - n ) ( 1 - α ) {K}_{f} / K} \qquad Eq . ( 18 )$$

In Eq. (18), K_{f} is a bulk modulus of drilling mud associated with the subterranean formation 118 and n is a porosity of the subterranean formation 118. In some examples, the shearing modulus and the bulk modulus are determined by evaluating Eqs. (19) and (20), respectively.

$$G = \frac{E}{2 ( 1 + v )} \qquad Eq . ( 19 )$$

$$K = \frac{E}{3 ( 1 - 2 v )} \qquad Eq . ( 20 )$$

In Eqs. (19) and (20), E is a Young's modulus of the subterranean formation 118 and v is a Poisson's ratio of the subterranean formation 118. In some examples, the Young's modulus and the Poisson's ratio is determined based on data from the well log instrument 126 (for example, density logs).

At step 214, the wellbore system 100 determines whether the characteristic diffusion time is at least 10 times greater than an injection time associated with the fluid in the formation surrounding the borehole segment 137. The injection time represents a duration associated with the fluid being pumped into the borehole segment 137. In some examples, the wellbore system 100 defines the injection time to be between 1 and 100 minutes. In some examples, the injection time is 10 minutes.

For example, if the characteristic diffusion time is 100 minutes and the injection time is 1 minute, then the wellbore system 100 determines that the characteristic diffusion time is at least 10 times greater than the injection time. A low ratio of characteristic diffusion time to injection time indicates that the subterranean formation 118 is permeable while a high ratio indicates that the subterranean formation 118 is impermeable (or approximately impermeable). In some examples, a low ratio results when the characteristic diffusion time is at least 10 times less than the injection time and a high ratio results when the characteristic diffusion time is at least 10 times greater than the injection time.

At step 216, responsive to determining that the characteristic diffusion time is at least 10 times greater than the injection time, the wellbore system 100 predicts the breakdown pressure based on in-situ principal stresses of the formation, reservoir pore pressure of the formation, and a tensile strength of the formation. For example, the wellbore system 100 predicts the breakdown pressure based on in-situ principal stresses of the subterranean formation 118, reservoir pore pressure of the subterranean formation 118, and a tensile strength of the subterranean formation 118 when the characteristic diffusion time is at least 10 times greater than the injection time. In some examples, the wellbore system 100 determines that the perforation channel 138 is impermeable based on the permeability information from the well log instrument 126.

In some examples, the wellbore system 100 predicts the breakdown pressure based on the HW solution approach as part of step 216. As previously described, the HW solution approach is adapted from the work by Hubbert and Willis in 1957. In some examples, the HW solution approach includes predicting the breakdown pressure by evaluating Eq. (21).

P_{b}=3σ₃−σ₁+T+P₀ Eq. (21)

In Eq. (21), P_{b} is the breakdown pressure, σ₃ is the minimum in-situ principal stress along a first transverse direction of the borehole segment 137, σ₁ is the maximum in-situ principal stress along a second transverse direction of the borehole segment 137, T is the tensile strength of the formation, and P₀ is the reservoir pore pressure of the borehole segment 137. In some examples, the wellbore system 100 determines σ₁ using Eq. (2) and σ₃ using Eq. (3). In some examples, a user determines T based on physical testing of the rock of the subterranean formation 118 and inputs T into the wellbore system 100. In some examples, a user determines T based on information from the well log instrument 126. In some examples, a user tests one or more core plugs in a laboratory to determine T. In some examples, a MiniFrac test and/or a drillstem test is used to determine the in-situ stresses and pore pressures. In some examples, the second transverse direction is perpendicular to the first transverse direction.

At step 218, responsive to determining that the characteristic diffusion time is at least 10 times less than the injection time, the wellbore system 100 predicts the breakdown pressure based on a Poisson's ratio of the formation and a poroelastic parameter of the formation. For example, if the characteristic diffusion time is 1 minute and the injection time is 10 minutes, then the wellbore system 100 determines that the characteristic diffusion time is at least 10 times less than the injection time.

In some examples, the wellbore system 100 predicts the breakdown pressure based on the HF solution approach as part of step 218. As previously noted, the HF solution approach is adapted from the work by Haimson and Fairhurst in 1967. In some examples, determining the breakdown pressure based on the Poisson's ratio of the subterranean formation 118 and the poroelastic parameter of the subterranean formation 118 as part of the step 218 includes evaluating Eq. (22).

$${P}_{b} = \frac{3 {σ}_{3} - {σ}_{1} - 2 {P}_{0} + T}{2 - α \frac{1 - 2 v}{1 - v}} + {P}_{0} \qquad Eq . ( 22 )$$

In Eq. (22), P_{b} is the breakdown pressure, σ₃ is the minimum in-situ principal stress along a first transverse direction of the borehole segment 137, σ₁ is the maximum in-situ principal stress along a second transverse direction of the borehole segment 137, T is the tensile strength of the formation, P₀ is the reservoir pore pressure of the subterranean formation 118, α is a Biot coefficient of effective stress of the subterranean formation 118, and v is a Poisson's ratio of the subterranean formation 118. In some examples, the wellbore system 100 determines σ₁ using Eq. (2) and σ₃ using Eq. (3). In some examples, the second transverse direction is perpendicular to the first transverse direction.

In some examples, a user determines T based on physical testing of the rock of the subterranean formation 118 and inputs T into the wellbore system 100. In some examples, a user tests one or more core plugs in a laboratory to determine T. In some examples, a user determines T based on information from the well log instrument 126. In some examples, a user determines a based on physical testing of the rock of the subterranean formation 118 and inputs a into the wellbore system 100. In some examples, a user determines a based on information from the well log instrument 126.

At step 220, responsive to determining that the characteristic diffusion time is neither at least 10 times less nor at least 10 times greater than the injection time, the wellbore system 100 predicts the breakdown pressure based on a hydraulic property of the formation. For example, if the characteristic diffusion time is 1 minute and the injection time is 5 minutes, then the wellbore system 100 determines that the characteristic diffusion time is neither at least 10 times less nor at least 10 times greater than the injection time.

In some examples, the wellbore system 100 predicts the breakdown pressure based on the TAN solution approach as part of step 220. As previously described, the TAN solution approach is adapted from the work of Tran, Abousleiman and Nguyen in 2011. In some examples, determining the breakdown pressure based on the hydraulic property of the subterranean formation 118 includes determining the breakdown pressure based on the hydraulic property of the subterranean formation 118 and a presence of filter cake or mud cake within the subterranean formation 118 based on the TAN solution approach.

In some examples, the TAN approach is different from the AC approach because the TAN approach accounts for an additional affecting factor, for example, the mud cake on the wellbore wall. In some examples, this mud cake behaves like an extra porous layer and influences the fluid diffusion process. The AC solution approach does not consider this additional affecting factor.

In some examples, the tangential stress around borehole continues to evolve and is affected by the injection pressure during the time it takes for the fracturing fluid to diffuse over a distance on the order of the radius of the perforation channel 138. In this case, diffusion of the pore pressure and the fluid-mechanical interaction results in a poroelastic conditions.

In some examples, determining the breakdown pressure based on the hydraulic property of the subterranean formation 118 includes determining one or more Laplace and Fourier transforms. For example, the wellbore system 100 determines a poroelastic solution of tangential stress around the borehole segment 137 with filter cake and/or mud cake by evaluating the Laplace transformation of Eq. (23) and the wellbore system 100 determines a poroelastic solution of pore pressure around the perforation channel 138 with filter cake and/or mud cake by evaluating the Laplace transformation of Eq. (24).

$${\tilde{σ}}_{θ θ} = 2 G \{ \frac{B ( 1 + {v}_{u} )}{3 ( 1 - {v}_{u} )} {C}_{1} \frac{{K}_{1} ( \sqrt{\frac{s}{c} r} )}{\sqrt{\frac{s}{c} r}} + \frac{{C}_{2}}{{r}^{2}} \} - \frac{2 GBv ( 1 + {v}_{u} )}{3 ( 1 - 2 v ) ( 1 - {v}_{u} )} {C}_{1} {K}_{0} ( \sqrt{\frac{s}{c} r} ) + \frac{α c}{κ} {C}_{1} {K}_{0} ( \sqrt{\frac{s}{c} r} ) + \{ \frac{2 GB ( 1 + {v}_{u} )}{3 ( 1 - {v}_{u} )} {C}_{3} [ \frac{{K}_{1} ( \sqrt{\frac{s}{c} r} )}{\sqrt{\frac{s}{c} r}} + ( 1 + \frac{6}{{r}^{2 \frac{s}{c}}} ) {K}_{2} ( \sqrt{\frac{s}{c} r} ) + \frac{6 {GC}_{5}}{{r}^{4}} ] \} cos [ 2 ( θ - {θ}_{r} ) ] \qquad Eq . ( 23 )$$

$$\tilde{P} = \frac{c}{κ} {C}_{1} {K}_{0} ( \sqrt{\frac{s}{c} r} ) + ⌈ \frac{2 {{GB}^{2} ( 1 + {v}_{u} )}^{2} ( 1 - v )}{9 ( {v}_{u} - v ) ( 1 - {v}_{u} )} {C}_{3} {K}_{2} ( \sqrt{\frac{s}{c} r} ) -- \frac{2 GB ( 1 + {v}_{u} ) {C}_{4}}{3 ( 1 - {v}_{u} ) {r}^{2}} ⌉ cos [ 2 ( θ - {θ}_{r} ) ] \qquad Eq . ( 24 )$$

The wellbore system 100 determines the parameters of Eqs. (23) and (24) by evaluating Eqs. (25)-(31).

$${C}_{1} = \frac{s \hat{g} ( s ) {\tilde{P}}_{m} - \tilde{g} ( s ) {P}_{0}}{μ R \sqrt{cs} {K}_{1} ( \sqrt{\frac{s}{c}} R ) + \frac{c}{κ} s \tilde{g} ( s ) {K}_{0} ( \sqrt{\frac{s}{c}} R )} \qquad Eq . ( 25 )$$

$${C}_{2} = \frac{{R}^{2}}{2 G} [ - {\tilde{P}}_{m} + \frac{{M}_{0}}{s} - \frac{2 GB ( 1 + {v}_{u} )}{3 ( 1 + {v}_{u} )} {C}_{1} \frac{{K}_{1} ( \sqrt{\frac{s}{c}} R )}{\sqrt{\frac{s}{c}} R} ] \qquad Eq . ( 26 )$$

$${C}_{3} = - \frac{{S}_{0}}{s} \frac{4 + 2 \frac{s \tilde{g} ( s )}{{k}_{f}}}{{D}_{1} - {D}_{2}} \qquad Eq . ( 27 )$$

$${C}_{4} = - \frac{{S}_{0}}{s} \frac{2 ( 1 - {v}_{u} ) {R}^{2}}{G} \frac{{D}_{2}}{{D}_{1} - {D}_{2}} \qquad Eq . ( 28 )$$

$${C}_{5} = \frac{{S}_{0}}{s} \frac{{R}^{4} ( \frac{4}{\sqrt{\frac{s}{c}} R} \frac{{K}_{2} ( \sqrt{\frac{s}{c}} R )}{{K}_{1} ( \sqrt{\frac{s}{c}} R )} {D}_{1} + {D}_{1} + {D}_{2} )}{2 G ( {D}_{1} - {D}_{2} )} \qquad Eq . ( 29 )$$

$${D}_{1} = \frac{2 GB ( 1 + {v}_{u} )}{3 ( 1 - {v}_{u} )} \frac{{K}_{1} ( \sqrt{\frac{s}{c}} R )}{\sqrt{\frac{s}{c}} R} ( 2 + \frac{s \hat{g} ( s )}{{k}_{f}} ) \qquad Eq . ( 30 )$$

$${D}_{2} = \frac{GB ( 1 + {v}_{u} ) ( 1 - v )}{3 ( {v}_{u} - v ) ( 1 - {v}_{u} )} [ \text{} {K}_{2} ( \sqrt{\frac{s}{c}} R ) \frac{s \hat{g} ( s )}{{k}_{f}} + R \sqrt{\frac{s}{c}} {K}_{1} ( \sqrt{\frac{s}{c}} R ) + 2 {K}_{2} ( \sqrt{\frac{s}{c}} R ) ] \qquad Eq . ( 31 )$$

The wellbore system 100 determines the evolution of the tangential stress (σ_{θθ}) and pore pressure (P) in the time domain by applying a Laplace inversion to Eqs. (23) and (24). The wellbore system 100 predicts the breakdown pressure (P_{b}) based on the borehole pressure Pₘ for which the peak value of the effective tangential stress on the borehole segment 137 wall first exceeds the tensile strength T. The wellbore system 100 predicts the breakdown pressure by evaluating Eq. (32).

(σ_{θθ}−P)_{r=R}=T Eq. (32)

In some examples, solving Eq. (32) involves solving for many nonlinear terms which can be difficult. In some examples, the wellbore system 100 predicts the breakdown pressure by iteratively changing the pressure and calculating the effective stress at one or more critical spots on the borehole segment 137 wall in the time domain of interest to predict the breakdown pressure, P_{b}.

At step 222, a hydraulic pump pumps the fluid into the borehole segment of the borehole to cause the subterranean formation surrounding the perforation channel to fracture at the predicted breakdown pressure. For example, the hydraulic pump 147 pumps fluid into the borehole segment 137 to cause the subterranean formation 118 to fracture.

In some examples, the wellbore system 100 recovers oil from the borehole 104 after the subterranean formation 118 has been fractured. For example, oil is displaced from the borehole 104 through the fractured subterranean formation 118 surrounding the borehole segment 137. In some examples, the wellbore system 100 includes an additional injection borehole to assist the displacement of oil from the borehole 104 by waterflooding.

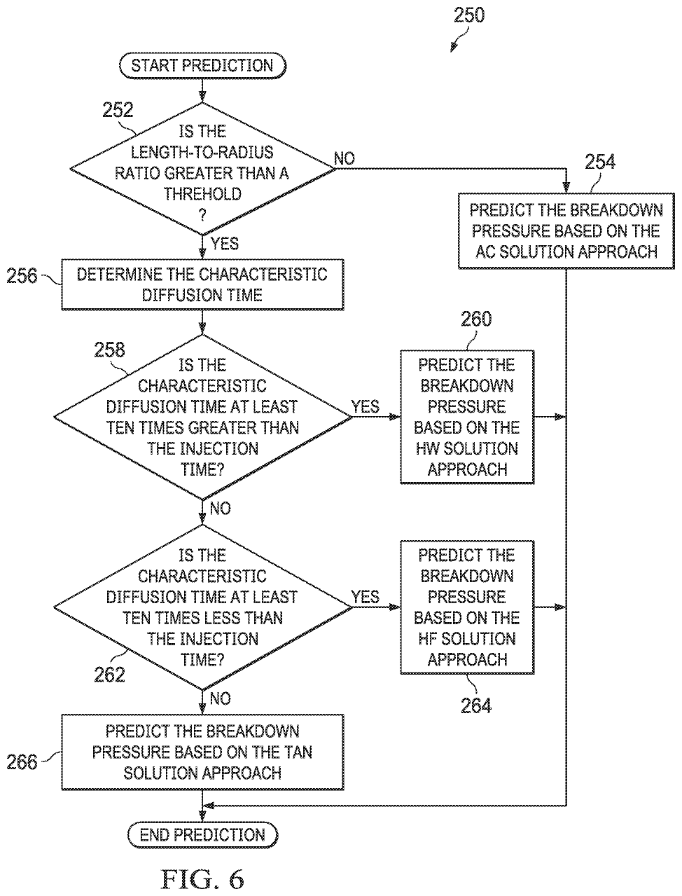

FIG. 6 is a flowchart of a decision process 250 performed by the wellbore system 100. The decision process 250 reflects the same steps and/or similar steps described with reference to the method 200 of FIGS. 2A and 2B.

At step 252, the wellbore system 100 determines if the length-to-radius ratio is greater than a threshold. If the wellbore system 100 determines that the length-to-radius ratio is not greater than the threshold, the wellbore system 100 proceeds to step 254 and predicts the breakdown pressure based on the AC solution approach. However, if the wellbore system 100 determines that the length-to-radius ratio is greater than the threshold, the wellbore system 100 proceeds to step 256 and determines the characteristic diffusion time.

At step 258, the wellbore system 100 determines if the characteristic diffusion time is at least 10 times greater than an injection time. If the wellbore system 100 determines that the characteristic diffusion time is at least 10 times greater than the injection time, the wellbore system 100 proceeds to step 260 and predicts the breakdown pressure based on the HW solution approach. However, if the wellbore system 100 determines that the characteristic diffusion time is not at least 10 times greater than the injection time, the wellbore system 100 proceeds to step 262.

At step 262, the wellbore system 100 determines if the characteristic diffusion time is at least 10 times less than the injection time. If the wellbore system 100 determines that the characteristic diffusion time is at least 10 times less than the injection time, the wellbore system 100 proceeds to step 264 and predicts the breakdown pressure based on the HF solution approach. However, if the wellbore system 100 determines that the characteristic diffusion time is not at least 10 times less than the injection time, the wellbore system 100 proceeds to step 266. At step 266, the wellbore system 100 predicts the breakdown pressure based on the TAN solution approach.

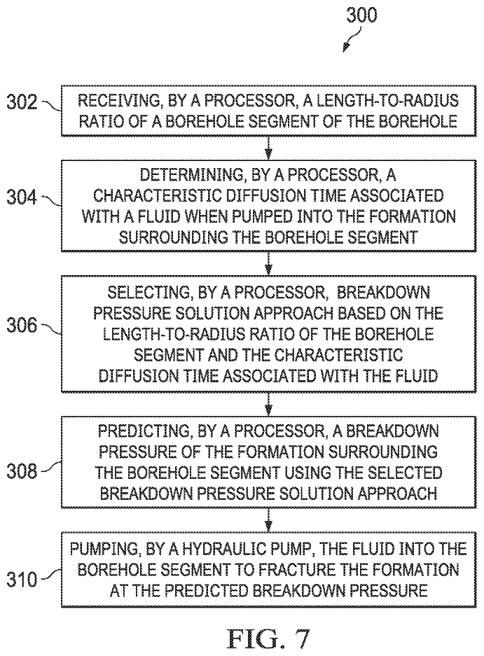

FIG. 7 is a flowchart of a method 300 for hydraulic fracturing a formation of a wellbore. In some examples, the wellbore system 100 performs the steps of method 300 in a similar manner as the wellbore system 100 performs the steps of method 200.

At step 302, the wellbore system 100 receives a length-to-radius ratio of a borehole segment of the wellbore. At step 304, the wellbore system 100 determines a characteristic diffusion time associated with a fluid when pumped into the formation surrounding the borehole segment. At step 306, the wellbore system 100 selects a breakdown pressure solution approach based on the length-to-radius ratio of the borehole segment of the wellbore and the characteristic diffusion time associated with the fluid. At step 308, the wellbore system 100 determines a breakdown pressure of the formation surrounding the borehole segment using the selected breakdown pressure solution approach. At step 310, the wellbore system 100 controls a hydraulic pump to pump the fluid into the borehole segment to fracture the formation at the determined breakdown pressure.

In some examples, determining the characteristic diffusion time associated with the fluid when pumped into the formation surrounding the borehole segment includes evaluating an expression as a function of a diffusivity of the fluid and a diffusion length of the formation. In some examples, evaluating the expression as a function of a diffusivity of the fluid and a diffusion length of the formation includes evaluating expression is Eq. (15). In some examples, the wellbore system 100 determines the diffusion length of the formation using a simulation model of the borehole.

In some examples, selecting the breakdown pressure solution approach includes determining that the characteristic diffusion time is at least 10 times greater than an injection time. In some examples, the injection time represents a duration associated with the fluid being pumped into the borehole segment by the pump. In some examples, determining the breakdown pressure includes, responsive to determining that the characteristic diffusion time is at least 10 times greater than the injection time, predicting the breakdown pressure based on in-situ principal stresses of the formation, reservoir pore pressure of the formation, and a tensile strength of the formation based on the HW solution approach.

In some examples, responsive to determining that the characteristic diffusion time is at 10 times less than the injection time, the wellbore system 100 predicts the breakdown pressure based on a Poisson's ratio of the formation and a poroelastic parameter of the formation based on the HF solution approach. In some examples, responsive to determining that the characteristic diffusion time is neither at least 10 times less nor at least 10 times greater than the injection time, the wellbore system 100 predicts the breakdown pressure based on a hydraulic property of the formation based on the TAN solution approach.

Examples are presented below to illustrate how the wellbore system 100 specifically predicts breakdown pressure for four example scenarios.

### Example 1

Step 1: Define/Receive Geometry Information, Stress Information, Pressure Information, and Properties of the Borehole and the Subterranean Formation.

Fluid is injected inside a horizontal borehole to fracture the formation surrounding the borehole. The injection borehole interval has a radius (R) of 0.1 m and length (2b) of 20 m. In-situ stresses include a vertical stress calculated from a density log of σ₁=σ_{V}=20 MPa, a minimum horizontal stress determined by a MiniFrac test of σ₃=σₕ=18 MPa, and a maximum horizontal stress equaling same minimum horizontal stress in this particular case of σ_{H}=18 MPa. The formation pore pressure measured by a drillstem test is P₀=10 MPa. The mechanical and hydraulic properties are measured in a laboratory and include a Young's modulus of E=30 GPa, a Poisson's ratio of v=0.12, a tensile strength of T=13 MPa, a porosity of v=0.1, and a permeability of k=10⁻⁵ millidarcy (md).

Step 2: Transform the Stress to the Borehole Coordinate System.

Since this is a horizontal borehole, the maximum and minimum horizontal stresses are equal. No stress transformation is required.

Step 3. Calculate Length-to-Radius Ratio (b/R) and Select Solution Approach.

b/R=100. b/R is much greater than 10, so the AC solution is not selected to predict the breakdown pressure.

Step 4. Calculate Characteristic Diffusion Time (t_{c}) and Select Solution Approach.

t_{c}=100 hours. The characteristic diffusion time t_{c} is much greater than a typical injection duration (for example, between 1 and 100 minutes). The wellbore system 100 selects the HW solution approach and predicts the breakdown pressure using the following expression:

P_{b}=3σ₃−σ₁+T+P₀=3×18−20+13−10=37 MPa.

The wellbore system 100 predicts the breakdown pressure to be 37 MPa for the horizontal wellbore in example 1.

### Example 2

The in-situ stresses and pore pressure, borehole trajectory and geometry, and formation tensile strength are same as example 1, but the permeability of the formation is k=1 md instead of k=10 md. In addition, the formation's Biot coefficient is 0.65.

The characteristic time of diffusion process t_{c} is about 20 seconds. In some examples, a characteristic diffusion time less than 1 minute is considered instantaneous in relation to a typical injection duration. The wellbore system 100 selects the HF solution approach and predicts the breakdown pressure using the following expression:

$${P}_{b} = \frac{3 {σ}_{3} - {σ}_{1} - 2 {P}_{0} + T}{2 - α \frac{1 - 2 v}{1 - v}} + {P}_{0} = \frac{3 \times 18 - 20 - 2 \times 10 + 13}{2 - 0.65 \times \frac{1 - 2 \times 0.12}{1 - 0.12}} + 10 = 29 MPa .$$

The wellbore system 100 predicts the breakdown pressure to be 29 MPa for the horizontal wellbore in example 2.

### Example 3

The in-situ stresses and pore pressure, borehole trajectory and geometry, and formation tensile strength are same as example 1, but the formation's permeability is k=0.01 md instead of k=10⁻⁵ md. The characteristic time t_{c} is about 33 minutes, which is in the same order as a typical injection duration (for example, between 1 minute and 100 minutes). A layer of filter cake is not present. In this case, the wellbore system 100 selects the TAN solution approach and predicts the breakdown pressure to be 28.7 MPa. However, if filter cake is present around the borehole with a thickness of 2 mm and having a permeability of 0.0001 md, the wellbore system 100 predicts the breakdown pressure to be 29.8 MPa.

### Example 4

The in-situ stresses and pore pressure, borehole trajectory and radius, and formation tensile strength are same as example 1, but the permeability of the formation is k=0.1 md instead of k=10⁻⁵ md. The borehole interval length is 1 m. Following the same procedure as example 1 and considering b/R is 5, the wellbore system 100 selects the AC solution approach and determines the breakdown pressure to be 46 MPa.

FIG. 8 is a schematic illustration of an example controller 280 (or control system) for determining a subterranean formation breakdown pressure according to the present disclosure. For example, the controller 280 may include or be part of the control system 146 shown in FIG. 1. The controller 280 is intended to include various forms of digital computers, such as printed circuit boards (PCB), processors, digital circuitry, or otherwise parts of a system for determining a subterranean formation breakdown pressure. Additionally the system can include portable storage media, such as, Universal Serial Bus (USB) flash drives. For example, the USB flash drives may store operating systems and other applications. The USB flash drives can include input/output components, such as a wireless transmitter or USB connector that may be inserted into a USB port of another computing device.

The controller 280 includes a processor 282, a memory 284, a storage device 286, and an input/output device 288 (for example, displays, input devices, sensors, valves, pumps). Each of the components 282, 284, 286, and 288 are interconnected using a system bus 290. The processor 282 is capable of processing instructions for execution within the controller 280. The processor may be designed using any of a number of architectures. For example, the processor 282 may be a CISC (Complex Instruction Set Computers) processor, a RISC (Reduced Instruction Set Computer) processor, or a MISC (Minimal Instruction Set Computer) processor.

In one implementation, the processor 282 is a single-threaded processor. In another implementation, the processor 282 is a multi-threaded processor. The processor 282 is capable of processing instructions stored in the memory 284 or on the storage device 286 to display graphical information for a user interface on the input/output device 288.

The memory 284 stores information within the controller 280. In one implementation, the memory 284 is a computer-readable medium. In one implementation, the memory 284 is a volatile memory unit. In another implementation, the memory 284 is a non-volatile memory unit.

The storage device 286 is capable of providing mass storage for the controller 280. In one implementation, the storage device 286 is a computer-readable medium. In various different implementations, the storage device 286 may be a floppy disk device, a hard disk device, an optical disk device, or a tape device.

The input/output device 288 provides input/output operations for the controller 280. In one implementation, the input/output device 288 includes a keyboard and/or pointing device. In another implementation, the input/output device 288 includes a display unit for displaying graphical user interfaces.

The features described can be implemented in digital electronic circuitry, or in computer hardware, firmware, software, or in combinations of them. The apparatus can be implemented in a computer program product tangibly embodied in an information carrier, for example, in a machine-readable storage device for execution by a programmable processor, and method steps can be performed by a programmable processor executing a program of instructions to perform functions of the described implementations by operating on input data and generating output. The described features can be implemented advantageously in one or more computer programs that are executable on a programmable system including at least one programmable processor coupled to receive data and instructions from, and to transmit data and instructions to, a data storage system, at least one input device, and at least one output device. A computer program is a set of instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

Suitable processors for the execution of a program of instructions include, by way of example, both general and special purpose microprocessors, and the sole processor or one of multiple processors of any kind of computer. Generally, a processor will receive instructions and data from a read-only memory or a random access memory or both. The essential elements of a computer are a processor for executing instructions and one or more memories for storing instructions and data. Generally, a computer will also include, or be operatively coupled to communicate with, one or more mass storage devices for storing data files; such devices include magnetic disks, such as internal hard disks and removable disks; magneto-optical disks; and optical disks. Storage devices suitable for tangibly embodying computer program instructions and data include all forms of non-volatile memory, including by way of example semiconductor memory devices, such as EPROM, EEPROM, and flash memory devices; magnetic disks such as internal hard disks and removable disks; magneto-optical disks; and CD-ROM and DVD-ROM disks. The processor and the memory can be supplemented by, or incorporated in, ASICs (application-specific integrated circuits).

To provide for interaction with a user, the features can be implemented on a computer having a display device such as a CRT (cathode ray tube) or LCD (liquid crystal display) monitor for displaying information to the user and a keyboard and a pointing device such as a mouse or a trackball by which the user can provide input to the computer. Additionally, such activities can be implemented via touchscreen flat-panel displays and other appropriate mechanisms.

The features can be implemented in a control system that includes a back-end component, such as a data server, or that includes a middleware component, such as an application server or an Internet server, or that includes a front-end component, such as a client computer having a graphical user interface or an Internet browser, or any combination of them. The components of the system can be connected by any form or medium of digital data communication such as a communication network. Examples of communication networks include a local area network (“LAN”), a wide area network (“WAN”), peer-to-peer networks (having ad-hoc or static members), grid computing infrastructures, and the Internet.

While this specification contains many specific implementation details, these should not be construed as limitations on the scope of any inventions or of what may be claimed, but rather as descriptions of features specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

A number of implementations have been described. Nevertheless, it will be understood that various modifications may be made without departing from the spirit and scope of the disclosure. For example, example operations, methods, or processes described herein may include more steps or fewer steps than those described. Further, the steps in such example operations, methods, or processes may be performed in different successions than that described or illustrated in the figures. Accordingly, other implementations are within the scope of the following claims.

What is claimed is:

1. A method of hydraulic fracturing a formation of a borehole, the method comprising:
receiving, by a processor, a length-to-radius ratio of a borehole segment of the borehole;
determining, by the processor, when the length-to-radius ratio is less than a threshold;
responsive to determining that the length-to-radius ratio is less than the threshold, predicting, by the processor, a breakdown pressure associated with a formation surrounding the borehole segment based on a length of the borehole segment;
responsive to determining that the length-to-radius ratio is greater than or equal to the threshold,
determining, by the processor, a characteristic diffusion time associated with a fluid diffusing into the formation surrounding the borehole segment;
determining, by the processor, whether the characteristic diffusion time is at least 10 times greater than an injection time associated with the fluid in the formation surrounding the borehole segment, the injection time representing a duration of time associated with the fluid being pumped into the borehole segment;
responsive to determining that the characteristic diffusion time is at least 10 times greater than the injection time, predicting, by the processor, the breakdown pressure based on in-situ principal stresses acting on the borehole segment, reservoir pore pressure of the formation, and a tensile strength of the formation; and
responsive to determining that the characteristic diffusion time is at least 10 times less than the injection time, predicting, by the processor, the breakdown pressure based on a Poisson's ratio of the formation and a poroelastic parameter of the formation;
responsive to determining that the characteristic diffusion time is neither at least 10 times less nor at least 10 times greater than the injection time, predicting the breakdown pressure based on a hydraulic property of the formation; and
pumping, by a hydraulic pump, the fluid into the borehole segment of the borehole to cause the formation surrounding the borehole segment to fracture at the predicted breakdown pressure.

2. The method of claim 1, further comprising measuring the length-to-radius ratio of the borehole segment of the borehole.

3. The method of claim 2, wherein measuring the length-to-radius ratio of the borehole segment of the borehole comprises logging the borehole to produce one or more well logs, and using the one or more well logs to determine the length-to-radius ratio.

4. The method of claim 1, wherein the borehole segment is a perforation channel of the borehole.

5. The method of claim 1, wherein the threshold is between 5 and 15.

6. The method of claim 5, wherein the threshold is 10.

7. The method of claim 1, wherein predicting the breakdown pressure based on the hydraulic property of the formation comprises predicting the breakdown pressure based on the hydraulic property of the formation and a presence of filter cake or mud cake within the formation.

8. The method of claim 1, further comprising:
receiving, by the processor, an inclination angle of the borehole segment; and
transforming, by the processor, the in-situ principal stresses associated with formation surrounding the borehole segment based of the inclination angle of the borehole segment.

9. The method of claim 8, further comprising logging the borehole to produce one or more well logs and using the one or more well logs to determine the inclination angle of the borehole segments.

10. The method of claim 1, wherein predicting the breakdown pressure based on the in-situ principal stresses acting on the borehole segment, the reservoir pore pressure of the formation, and the tensile strength of the formation, comprises evaluating: P_{b}=3σ₃−σ₁+T+P₀, wherein P_{b} is the breakdown pressure, σ₃ is a minimum in-situ principal stress along a first transverse direction of the borehole segment, σ₁ is a maximum in-situ principal stress along a second transverse direction of the borehole segment, T is the tensile strength of the formation, and P₀ is the reservoir pore pressure of the borehole.

11. The method of claim 1, wherein determining the breakdown pressure based on the Poisson's ratio of the formation and the poroelastic parameter of the formation comprises evaluating:
$${P}_{b} = {P}_{b} = \frac{3 {σ}_{3} - {σ}_{1} - 2 {P}_{0} + T}{2 - α \frac{1 - 2 v}{1 - v}} + {P}_{0} ,$$
wherein P_{b} is the breakdown pressure, σ₃ is a minimum in-situ principal stress along a first transverse direction of the borehole segment, σ₁ is a maximum in-situ principal stress along a second transverse direction of the borehole segment, T is the tensile strength of the formation, P₀ is the reservoir pore pressure of the formation, α is a Biot coefficient of effective stress of the formation, and v is a Poisson's ratio of the formation.

12. The method of claim 1, wherein determining the breakdown pressure based on the length of the borehole segment and predicting the breakdown pressure based on a hydraulic property of the formation comprises determining one or more Laplace and Fourier transforms.

13. The method of claim 1, wherein determining the characteristic diffusion time associated with the fluid in the formation surrounding the borehole segment comprises evaluating: t_{c}=L_{c}²/c where t_{c} is the characteristic diffusion time, c is a diffusivity of the fluid in the formation, and L_{c} is a diffusion length.

14. The method of claim 13, further comprising determining the diffusion length of the formation using a simulation model of the borehole.

15. A method of hydraulic fracturing a formation of a borehole, the method comprising:
receiving, by a processor, a length-to-radius ratio of a borehole segment of the borehole;
determining, by the processor, a characteristic diffusion time associated with a fluid when pumped into the formation surrounding the borehole segment;
selecting, by the processor, a breakdown pressure solution approach based on (i) the length-to-radius ratio of the borehole segment and (ii) the characteristic diffusion time associated with the fluid;
predicting, by the processor, a breakdown pressure of the formation surrounding the borehole segment using the selected breakdown pressure solution approach; and
pumping, by a hydraulic pump, the fluid into the borehole segment to fracture the formation at the predicted breakdown pressure.

16. The method of claim 15, further comprising measuring, by a well log instrument, the length-to-radius ratio of the borehole segment.

17. The method of claim 15, wherein determining the characteristic diffusion time associated with the fluid when pumped into the formation surrounding the borehole segment comprises evaluating an expression as a function of a diffusivity of the fluid and a diffusion length of the formation.

18. A system comprising:
a well log instrument operable to measure a length-to-radius ratio of a borehole segment of a borehole;
a hydraulic pump operable to pump a fluid into the borehole:
one or more processors configured to perform operations comprising:
receiving the measured length-to-radius ratio of the borehole segment from the well log instrument;
determining a characteristic diffusion time associated with the fluid when pumped into a formation surrounding the borehole segment;
selecting a breakdown pressure solution approach based on (i) the measured length-to-radius ratio of the borehole segment and (ii) the characteristic diffusion time associated with a diffusion of the fluid into the formation surrounding the borehole segment;
predicting the breakdown pressure of the formation surrounding the borehole segment using the selected breakdown pressure solution approach; and
controlling the hydraulic pump to pump the fluid into the borehole segment at a pressure greater than or equal to the predicted breakdown pressure to fracture the formation surrounding the borehole segment.

19. The system of claim 18, wherein selecting the breakdown pressure solution approach comprises determining when the characteristic diffusion time is at least 10 times greater than an injection time, the injection time representing a duration of time associated with the fluid being pumped into the borehole segment by the pump.

20. The system of claim 19, wherein predicting the breakdown pressure comprises:
responsive to determining that the characteristic diffusion time is at least 10 times greater than the injection time, predicting the breakdown pressure based on in-situ principal stresses acting on the borehole segment, a reservoir pore pressure of the formation, and a tensile strength of the formation;
responsive to determining that the characteristic diffusion time is at least 10 times less than the injection time, predicting the breakdown pressure based on a Poisson's ratio of the formation and a poroelastic parameter of the formation; and
responsive to determining that the characteristic diffusion time is neither at least 10 times less nor at least 10 times greater than the injection time, predicting the breakdown pressure based on a hydraulic property of the formation.
